(19) United States
(12) Patent Application Publication
(10) Pub. No.: US 2026/0157172 A1
(43) Pub. Date: Jun. 4, 2026

(54) SEMICONDUCTOR DEVICE

(71) Applicant: FUJI ELECTRIC CO., LTD., Kawasaki-shi (JP)

(72) Inventor: Hitoshi NAKATA, Matsumoto-city (JP)

(73) Assignee: FUJI ELECTRIC CO., LTD., Kawasaki-shi (JP)

(21) Appl. No.: 19/376,126

(22) Filed: Oct. 31, 2025

(30) Foreign Application Priority Data
Dec. 4, 2024 (JP) 2024-211169

(51) Int. Cl. H01L 23/367; H01L 21/48; H01L 23/00; H01L 23/31; H01L 23/373; H01L 25/065

(52) U.S. Cl. CPC H10W 40/22; H10W 40/251; H10W 74/114; H10W 99/00; H10W 90/00; H10W 90/734

(57) ABSTRACT

To suppress pump-out and degradation of a heat-dissipating adhesive layer of a power semiconductor module, and to provide a highly reliable semiconductor device, the present invention provides a semiconductor device including: a semiconductor module in which a laminated substrate (2) on which a semiconductor element (1) is mounted is sealed with a sealing material (8); a heat-dissipating plate (3) bonded to the laminated substrate; a heat-dissipating adhesive layer (4) provided in contact with the heat-dissipating plate, the layer including a rubber elastic body and a filler; a cooling component (6) provided in contact with the heat-dissipating adhesive layer; and a protective layer (5) that covers at least a part of a surface of the heat-dissipating adhesive layer, wherein the protective layer includes a silicone compound and a filler, and has a tensile strength of 0.2 to 4.5 MPa.

### CROSS-REFERENCE TO RELATED APPLICATION

This application claims priority from Japanese Patent Application No. 2024-211169, filed on Dec. 4, 2024, which is incorporated herein by reference in its entirety.

### FIELD OF THE INVENTION

The present invention relates to semiconductor devices. The present invention particularly relates to highly reliable semiconductor devices with excellent heat dissipation characteristics.

### BACKGROUND OF THE INVENTION

Power semiconductor modules are widely used in fields in which efficient power conversion is required. Examples include fields of renewable energy such as solar power generation and wind power generation, which have been gaining attention in recent years, in fields of vehicles such as hybrid and electric vehicles, and in railway sectors such as rolling stock and related equipment. These power semiconductor modules have built-in switching elements and diodes, and Si (silicon) semiconductors and SiC (silicon carbide) semiconductors have been used as the elements. These power semiconductor modules are installed on a cooling component via a heat-dissipating adhesive layer and are used as a power semiconductor device.

### DESCRIPTION OF RELATED ART

The heat-dissipating adhesive layer is a bonding layer formed between a heat-dissipating plate or a conductive plate on the back surface of the power semiconductor module and a cooling component in order to dissipate heat generated in a semiconductor chip to the cooling component or the like, and a heat-dissipating bonding layer is used made of a thermally conductive material (Thermal Interface Material: TIM) having thermal conductivity and insulating properties. As one example, a semiconductor device is known that includes a semiconductor module provided with a laminated substrate on which a semiconductor element is mounted and a sealing material, and a cooling component disposed on the semiconductor module via a thermal compound that includes a filler containing high dielectric-constant particles with a relative permittivity of 10 or more, and a base oil (see, for example, Japanese Unexamined Patent Application Publication No. 2019-41013).

A semiconductor device is known that includes a semiconductor module having a heat-dissipating surface on a bottom part, a cooling component provided such that its surface opposes the heat-dissipating surface, a grease member provided in a filling region between the heat-dissipating surface of the semiconductor module and the surface of the cooling component, and a peripheral adhesion member formed on the surface of the cooling component, covering a side surface region of the grease member without any gaps (see, for example, International Publication No. WO2015/102046 A1).

### SUMMARY OF THE INVENTION

### Problem to be Solved by the Invention

As the importance of in-vehicle semiconductor modules increases, the problem of pump-out has become apparent, in which the module thermally deforms due to high temperatures of the semiconductor element, which is the heat source, and the TIM constituting the heat-dissipating adhesive layer is pushed out. When voids are formed in the space from which the material is pushed out by the pump-out, a problem could arise in which cooling efficiency deteriorates. Additionally, peeling could occur at the interface or within the heat-dissipating adhesive layer, possibly because moisture and corrosive gases from the outside infiltrate the heat-dissipating adhesive layer and degrade the TIM.

There is a demand to solve these problems and provide a highly reliable semiconductor device.

### Means for Solving the Problem

As a result of diligent investigation, the present inventor conceived of providing a highly reliable semiconductor device that suppresses pump-out by covering the heat-dissipating adhesive layer with a protective layer that satisfies specific physical property values, and thereby completed the present invention.

That is, according to one embodiment, the present invention relates to a semiconductor device, including: a semiconductor module in which a laminated substrate on which a semiconductor element is mounted is sealed with a sealing material; a heat-dissipating plate bonded to the laminated substrate; a heat-dissipating adhesive layer provided in contact with the heat-dissipating plate, the layer including a rubber elastic body and a filler; a cooling component provided in contact with the heat-dissipating adhesive layer; and a protective layer that covers at least a part of a surface of the heat-dissipating adhesive layer, wherein the protective layer includes a silicone compound and a filler, and has a tensile strength of 0.2 to 4.5 MPa.

In the semiconductor device, a ratio of the tensile strength of the protective layer to the tensile strength of the heat-dissipating adhesive layer is preferably 1.25 to 26.

In the semiconductor device, the tensile strength of the protective layer is preferably 0.2 to 3 MPa.

In the protective layer of the semiconductor device, it is preferable that the silicone compound include polysiloxane, and that the filler include Al₂O₃ (alumina) or BN (boron nitride).

In the semiconductor device, it is preferable that the filler of the protective layer be included in an amount of 60% by mass or more and 98% by mass or less with respect to a total mass of the protective layer.

In the semiconductor device, it is preferable that the protective layer be provided discontinuously along a periphery of the heat-dissipating adhesive layer.

In the semiconductor device, a width of the protective layer is preferably 0.5 mm or more.

The present invention relates to a method for manufacturing the aforementioned semiconductor device, the method including steps of: preparing the semiconductor module in which the heat-dissipating plate is bonded to a back surface of the laminated substrate; forming the heat-dissipating adhesive layer in contact with the heat-dissipating plate; forming the protective layer, wherein the protective layer is formed so as to protrude from a principal surface of the heat-dissipating adhesive layer; and pressure-bonding the cooling component to the protruding protective layer and bringing the cooling component and the heat-dissipating adhesive layer into contact.

In the method for manufacturing the semiconductor device, it is preferable that the step of forming the protective layer be performed before the step of forming the heat-dissipating adhesive layer.

In the method for manufacturing the semiconductor device, it is preferable that the step of forming the heat-dissipating adhesive layer be performed before the step of forming the protective layer.

In the method for manufacturing the semiconductor device, it is preferable that the step of pressure-bonding be performed with a force of 200 to 300 N.

### Effects of the Invention

According to the semiconductor device according to the present invention, pump-out and degradation of the heat-dissipating adhesive layer can be suppressed, and a highly reliable semiconductor device can be provided.

### BRIEF DESCRIPTION OF THE DRAWINGS

FIG. 1 is a conceptual diagram showing a cross-sectional structure of a semiconductor device according to an embodiment of the present invention;

FIG. 2 is a conceptual diagram showing a cross-sectional structure of a heat-dissipating structure portion, excluding a semiconductor module, in a semiconductor device according to a first embodiment of the present invention;

FIG. 3 is a plan view of the heat-dissipating structure portion of FIG. 2;

FIG. 4 is a conceptual diagram showing a cross-sectional structure of a heat-dissipating structure portion, excluding a semiconductor module, in a semiconductor device according to a second embodiment of the present invention;

FIG. 5 is a plan view of the heat-dissipating structure portion of FIG. 4;

FIG. 6 is a conceptual diagram showing a cross-sectional structure of a heat-dissipating structure portion, excluding a semiconductor module, in a semiconductor device according to a third embodiment of the present invention;

FIG. 7 is a plan view of the heat-dissipating structure portion of FIG. 6;

FIG. 8 is a graph plotting the number of heat cycles against the tensile strength of the protective layer in the semiconductor devices of Examples 1 to 14; and

FIG. 9 is a graph plotting the number of heat cycles against the ratio of the tensile strength of the protective layer to the tensile strength of the heat-dissipating adhesive layer in the semiconductor devices of Examples 1 to 14.

### DESCRIPTION OF PREFERRED EMBODIMENTS

Hereinafter, embodiments of the present invention will be described with reference to the drawings. However, the present invention is not limited to the embodiments described below.

According to one embodiment, the present invention relates to a semiconductor device. The semiconductor device includes a semiconductor module in which a laminated substrate, on which a semiconductor element is mounted, is sealed with a sealing material, a heat-dissipating plate bonded to the laminated substrate, a heat-dissipating adhesive layer provided in contact with the heat-dissipating plate, the layer including a rubber elastic body and a filler, a cooling component provided in contact with the heat-dissipating adhesive layer, and a protective layer that covers at least a part of a surface of the heat-dissipating adhesive layer, wherein the protective layer includes a silicone compound and a filler, and has a tensile strength of 0.2 to 4.5 MPa.

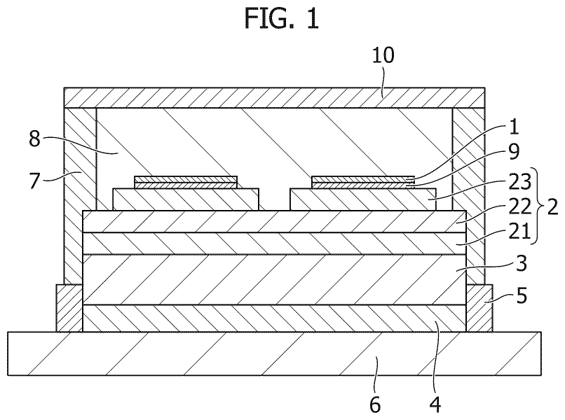

FIG. 1 is a conceptual diagram showing an example of a semiconductor device according to an embodiment of the present invention. In FIG. 1, a semiconductor element 1 is mounted on a laminated substrate 2 via a joining layer 9 such as solder. A conductive connection member (not shown) such as a lead frame, an aluminum wire, and/or an implant pin is connected to the upper surface of the semiconductor element 1 and is connected to a terminal or an electrode. The semiconductor element 1, the laminated substrate 2, and the conductive connection member are housed in a case 7 and sealed with a sealing material 8 that fills the case 7. The case 7 is provided with a lid 10 for protecting the interior. A member obtained by sealing at least a part of a member to be sealed, which includes at least the laminated substrate 2 on which the semiconductor element 1 is mounted, with the sealing material 8 in this manner is referred to as a semiconductor module. Therefore, a part of the laminated substrate 2 of the semiconductor module may be exposed without being completely covered by the sealing material 8. A heat-dissipating plate 3, a heat-dissipating adhesive layer 4, and a cooling component 6 are laminated and arranged, in this order, on the back surface of the laminated substrate 2 constituting the semiconductor module, that is, on the side opposite to the side on which the semiconductor element 1 is mounted. In this specification, the terms “upper surface” and “lower surface” are relative terms referring to the top and bottom in the drawing for the purpose of explanation, and do not limit the top and bottom in relation to the usage configuration and the like of the semiconductor device. Additionally, in the following specification, a member that includes the semiconductor element 1 and the laminated substrate 2 and is insulated and sealed with a sealing resin in a general sealing configuration is referred to as a member to be sealed.

The semiconductor element 1 is a power chip such as an IGBT or a diode chip, and various Si devices, SiC devices, GaN devices, and the like can be used. A combination of these devices may also be used. For example, a hybrid module using an Si-IGBT and a SiC-SBD can be used. The number of mounted semiconductor elements 1 is not limited to the illustrated configuration; one element may be mounted, or three or more elements may be mounted.

The laminated substrate 2 is typically composed of an insulating substrate 22, a second conductive plate 23 formed on one surface thereof, and a first conductive plate 21 formed on the other surface. As the insulating substrate 22, any material with excellent electrical insulation and thermal conductivity can be used. Examples of the material for the insulating substrate 22 include Al₂O₃ (alumina), AlN (aluminum nitride), SiN (silicon nitride), and the like. Particularly for high-voltage applications, a material that achieves both electrical insulation and thermal conductivity is preferable, and AlN or SiN can be used, but the material is not limited to these. The laminated substrate 2 may be a resin insulating substrate made of a thermosetting resin or the like. In that case, the resin insulating substrate may include a thermally conductive filler such as particulate alumina, silica (SiO₂), or boron nitride. As the first conductive plate 21 and the second conductive plate 23, metal materials with excellent processability such as copper and aluminum can be used. Copper or aluminum that has been treated with Ni plating or the like for purposes such as rust prevention may also be used. As a method for disposing the conductive plates 21 and 23 on the insulating substrate 22, a direct bonding method (Direct Copper Bonding method) or a brazing method (Active Metal Brazing method) can be mentioned. In this specification, the first conductive plate 21 may be formed integrally with a heat-dissipating plate 3, which will be described later.

The joining layer 9 can be formed using any joining material. As the joining material, for example, lead-free solder can be used, and lead-free solders such as Sn—Ag—Cu-based, Sn—Sb-based, Sn—Sb—Ag-based, Sn—Cu-based, Sn—Sb—Ag—Cu-based, Sn—Cu—Ni-based, and Sn—Ag-based solders can be used, but the material is not limited to these. The joining material may also include a sintered metal nanoparticle material such as a sintered Ag nanoparticle material.

In this embodiment, a member to be sealed, which includes the semiconductor element 1 and the laminated substrate 2 and may include a conductive connection member, terminals, etc. (not shown), is insulated and sealed with the sealing material 8. The sealing material 8 may be, for example, a thermosetting resin, and when the semiconductor device has a case, it may be a silicone gel. The thermosetting resin is preferably an epoxy resin, a maleimide resin, a cyanate resin, or a mixture thereof, and particularly preferably includes an epoxy resin. The sealing material 8 can, in a most preferred embodiment, be formed from an epoxy resin composition that includes an epoxy resin base, a curing agent, and optionally may include an inorganic filler and other additives. As the epoxy resin base, an aliphatic epoxy or a cycloaliphatic epoxy resin base can be used.

An aliphatic epoxy resin shall refer to an epoxy compound in which the carbon to which an epoxy group is directly bonded is a carbon constituting an aliphatic hydrocarbon. Therefore, even a compound containing an aromatic ring in its main skeleton is classified as an aliphatic epoxy resin if it meets the above condition. Examples of the aliphatic epoxy resin include bisphenol A type epoxy resin, bisphenol F type epoxy resin, bisphenol AD type epoxy resin, biphenyl type epoxy resin, cresol novolac type epoxy resin, and trifunctional or higher polyfunctional type epoxy resins, but the resin is not limited to these. These can be used alone or in a mixture of two or more kinds.

A cycloaliphatic epoxy resin shall refer to an epoxy compound in which the two carbon atoms constituting the epoxy group constitute a cycloaliphatic compound. Examples of the cycloaliphatic epoxy resin include monofunctional type epoxy resin, bifunctional type epoxy resin, and trifunctional or higher polyfunctional type epoxy resins, but the resin is not limited to these. Cycloaliphatic epoxy resins can also be used alone or in a mixture of two or more different kinds of cycloaliphatic epoxy resins.

The curing agent is not particularly limited, as long as it can react with the epoxy resin base and be cured, but it is preferable to use an acid anhydride-based curing agent.

Examples of the acid anhydride-based curing agent include aromatic acid anhydrides, specifically phthalic anhydride, pyromellitic anhydride, trimellitic anhydride, and the like. Alternatively, cyclic aliphatic acid anhydrides, specifically tetrahydrophthalic anhydride, methyltetrahydrophthalic anhydride, hexahydrophthalic anhydride, methylhexahydrophthalic anhydride, methylnadic anhydride, and the like, or aliphatic acid anhydrides, specifically succinic anhydride, polyadipic anhydride, polysebacic anhydride, polyazelaic anhydride, and the like can be mentioned. The blended amount of the curing agent is preferably about 50 parts by mass or more and 170 parts by mass or less, and more preferably about 80 parts by mass or more and 150 parts by mass or less, per 100 parts by mass of the epoxy resin base. If the blended amount of the curing agent is less than 50 parts by mass, the glass transition temperature may decrease due to insufficient cross-linking, and if it is more than 170 parts by mass, it may be accompanied by a decrease in moisture resistance, high-temperature deformation temperature, and heat-resistant stability.

A curing accelerator can be further added to the epoxy resin composition as an optional component. As the curing accelerator, imidazole or its derivatives, tertiary amines, boric acid esters, Lewis acids, organometallic compounds, organic acid metal salts, and the like can be appropriately blended. The added amount of the curing accelerator is preferably 0.01 parts by mass or more and 50 parts by mass or less, and more preferably 0.1 parts by mass or more and 20 parts by mass or less, per 100 parts by mass of the epoxy resin base.

As the inorganic filler that the epoxy resin composition may optionally include, fused silica, silica, alumina, aluminum hydroxide, titania, zirconia, aluminum nitride, talc, clay, mica, glass fibers, and the like, may be mentioned as examples, but the filler is not limited to these. These inorganic fillers can increase the thermal conductivity of the cured product and reduce the coefficient of thermal expansion. These inorganic fillers may be used alone, or two or more kinds may be used in a mixture. These inorganic fillers may be microfillers or nanofillers, and two or more kinds of inorganic fillers with different particle sizes and/or types can also be used in a mixture. In particular, it is preferable to use an inorganic filler with an average particle size of about 0.2 μm or more and 20 μm or less. The added amount of the inorganic filler is preferably 100 parts by mass or more and 600 parts by mass or less, and more preferably 200 parts by mass or more and 400 parts by mass or less, when the total mass of the epoxy resin base and the curing agent is 100 parts by mass. If the blended amount of the inorganic filler is less than 100 parts by mass, the coefficient of thermal expansion of the sealing material may be high, making peeling and cracking more likely to occur. If the blended amount is more than 600 parts by mass, the viscosity of the composition may increase, resulting in poor extrusion moldability.

The epoxy resin composition may also contain optional additives to the extent that they do not impair its properties. Examples of additives include flame retardants, pigments for coloring the resin, and plasticizers and silicone elastomers for improving crack resistance, but they are not limited to these. These optional components and their added amounts can be appropriately determined by one skilled in the art according to the specifications required for the semiconductor device and/or the sealing material.

The sealing material 8 is housed in the case 7 and is protected by the lid 10. According to other embodiments (not shown), the semiconductor module may not have a case and/or a lid, and a sealing material mainly composed of a thermosetting resin and containing an inorganic filler may be present in a state in which its surface is exposed. Although FIG. 1 shows the case 7 arranged, so as to be in contact with the laminated substrate 2 and the heat-dissipating plate 3, the case 7 may not be in contact with the laminated substrate 2 or the heat-dissipating plate 3, and the sealing material 8 may be arranged between them. Accordingly, on the back surface of the semiconductor module, an arrangement in which a lower end surface of the sealing material 8 or the case 7 is exposed is also possible.

On the back surface of the laminated substrate 2 of the semiconductor module, a heat-dissipating plate 3, a heat-dissipating adhesive layer 4, and a cooling component 6 are sequentially laminated, and a protective layer 5 that covers a side surface of the heat-dissipating adhesive layer 4 is provided. Hereinafter, in this specification, the heat-dissipating plate 3, the heat-dissipating adhesive layer 4, the cooling component 6, and the protective layer 5 are referred to as a heat-dissipating structure portion.

The heat-dissipating plate 3 is bonded to the back surface of the laminated substrate 2 with a thermally conductive joining material such as solder or metal nanoparticles. When the heat-dissipating plate 3 is integral with the first conductive plate 21, it is bonded to the insulating substrate 22 in the same manner as the first conductive plate 21. The heat-dissipating plate 3 may be a flat plate made of a material with high thermal conductivity, and may be a copper plate, a copper alloy plate, an aluminum plate, or an aluminum alloy plate, but it is not limited to these. The heat-dissipating plate 3 generally has a second principal surface that contacts the heat-dissipating adhesive layer 4 and a first principal surface that opposes the second principal surface, and is a rectangular parallelepiped member having four side surfaces that do not contact the semiconductor module and the heat-dissipating adhesive layer 4. The second principal surface of the heat-dissipating plate 3 may have a portion that is exposed without contacting the heat-dissipating adhesive layer 4. In this case, the second principal surface of the heat-dissipating plate 3 has a larger area than a first principal surface, to be described later, of the heat-dissipating adhesive layer 4. Such a configuration has an advantage that the bonding area between the heat-dissipating plate 3 and the heat-dissipating adhesive layer 4 can be made smaller, resulting in a smaller amount of deformation applied to the heat-dissipating adhesive layer 4 and making peeling less likely. In this specification, an interval between the first principal surface and the second principal surface is defined as the height of the heat-dissipating plate 3. The heat-dissipating plate 3 may be configured integrally with the first conductive plate 21 of the laminated substrate 2. The height of the heat-dissipating plate 3 is not particularly limited, but when the first conductive plate 21 exists in addition to the heat-dissipating plate 3, it may be, for example, 1.0 to 3.0 mm, and is preferably 1.5 to 2.0 mm. Alternatively, when the heat-dissipating plate 3 is configured integrally with the first conductive plate 21 of the laminated substrate 2, the height of the heat-dissipating plate 3 may be, for example, 1.0 to 4.0 mm, and is preferably 1.5 to 3.0 mm. The shape and dimensions of the principal surface of the heat-dissipating plate 3 are appropriately determined according to the specifications of the semiconductor module and are not particularly limited. The second principal surface of the heat-dissipating plate 3 at the stage of the semiconductor module before the heat-dissipating adhesive layer 4 and the protective layer 5 are provided may be exposed without being covered by the sealing material or the case, and a part of the four side surfaces may also be exposed. When a part of the four side surfaces of the heat-dissipating plate 3 is exposed, a distance between a lower surface of the sealing material or a lower end surface of the case and the second principal surface of the heat-dissipating plate 3 is referred to as an exposed height of the heat-dissipating plate 3.

The heat-dissipating adhesive layer 4 is a layer formed from a composition for a heat-dissipating adhesive layer that includes a rubber elastic body and a filler. Such a composition may also be referred to as a “compound”. Examples of the rubber elastic body include a silicone compound (silicone rubber), a fluororesin compound (fluoro rubber), heat-resistant urethane, nitrile rubber, chloroprene rubber, ethylene rubber, and butyl rubber, and these may also be referred to as rubber-based adhesives. From the viewpoint of heat resistance, fluoro rubber or silicone rubber is preferable, but the material is not limited to these. The heat-dissipating adhesive layer 4 may be, for example, sheet-shaped, or sheet-shaped with a recess provided to surround the heat-dissipating plate 3. Silicone rubber, which is an example of a preferable rubber elastic body, may be a polysiloxane having a siloxane bond as its main skeleton and organic groups such as alkyl groups and phenyl groups as side chains, and may also contain a vulcanizing agent. As the filler, inorganic compound particles with high thermal conductivity can be used, and Al₂O₃ (alumina), SiO₂ (silica), or BN (boron nitride), etc., can be used, but the material is not limited to these. The average particle size of the filler can be 10 to 200 μm, and is preferably 20 to 100 μm. A proportion of the filler in the total mass of the heat-dissipating adhesive layer 4 is preferably 90 to 99% by mass, and more preferably 90 to 95% by mass. Preferable physical properties of the heat-dissipating adhesive layer 4 after curing may be a density at 23° C. of 3 to 4 g/cm³, a Shore A hardness of 20 to 50, a tensile strength of 0.05 to 0.5 MPa, and an elongation at break of 20 to 50%, and it is preferable that it have good adhesion to a copper or copper alloy member. The elongation to breaking indicates the elongation at the time of breaking in a tensile strength test based on JIS K 6251. The Shore A hardness is measured with a durometer (type A) and is a relative numerical value of the repulsion amount of a spring when a probe is pressed against the surface of the object to be measured. For the heat-dissipating adhesive layer 4, a commercially available heat-dissipating gap filler or the like can be used, and for example, SDP-5040-A/B manufactured by Shin-Etsu Chemical Co., Ltd., SDP-6560-A/B manufactured by Shin-Etsu Chemical Co., Ltd., etc., can be used, but the material is not limited to these. One skilled in the art can also design and prepare a silicone rubber having the above preferable post-curing physical properties.

The heat-dissipating adhesive layer 4 is preferably formed in a substantially rectangular parallelepiped shape having a first principal surface that contacts the second principal surface of the heat-dissipating plate 3, a second principal surface that contacts the cooling component 6, and four side surfaces that do not contact the heat-dissipating plate 3 and the cooling component 6. However, the shape is not limited to a rectangular parallelepiped, and it can also be a shape with steps or a shape that contacts the second principal surface and the four side surfaces of the heat-dissipating plate 3 and surrounds five surfaces of the heat-dissipating plate 3 excluding the first principal surface. In this specification, a maximum dimension in a direction perpendicular to the first principal surface or the second principal surface of the heat-dissipating adhesive layer 4 is defined as the height of the heat-dissipating adhesive layer 4. Therefore, the height of the heat-dissipating adhesive layer 4 may be an interval between the first principal surface and the second principal surface of the heat-dissipating adhesive layer 4. When the heat-dissipating adhesive layer 4 is a sheet with a recess, the value may be larger than the interval between the first principal surface and the second principal surface. The height of the heat-dissipating adhesive layer 4 is not particularly limited, but it may be, for example, 0.02 mm to 0.2 mm, and is preferably 0.05 mm to 0.1 mm. The shape and dimensions of the principal surface of the heat-dissipating adhesive layer 4 are appropriately determined according to the specifications of the heat-dissipating plate 3 and the semiconductor module, and are not particularly limited. The principal surface of the heat-dissipating adhesive layer 4 may be formed larger than the principal surface of the heat-dissipating plate 3, or may be formed smaller.

The cooling component 6 is a member made of a material with high thermal conductivity, and may be a flat plate-shaped cooling plate or a heat sink with pin-shaped or bellows-shaped fins. A surface of the cooling component 6 that opposes the heat-dissipating adhesive layer 4 is preferably a flat surface, but it may be roughened or have irregularities. The material of the cooling component 6 may be copper, a copper alloy, aluminum, or an aluminum alloy, but it is not limited to these. The cooling component 6 is provided in contact with the second principal surface of the heat-dissipating adhesive layer 4 and a part of the protective layer 5. The semiconductor module and the cooling component 6 may be fixed by being pressed from the upper part of the semiconductor module (the lid 10 side) with a leaf spring (not shown) or be fastened with screws, via the heat-dissipating adhesive layer 4.

The protective layer 5 is in contact with the cooling component 6 and the heat-dissipating adhesive layer 4, covers at least a part of the side surface of the heat-dissipating adhesive layer 4, and optionally covers at least a part of a side surface and/or the second principal surface of the heat-dissipating plate 3. This prevents pump-out of the heat-dissipating adhesive layer 4, and also prevents the heat-dissipating adhesive layer 4 from degrading due to the surrounding atmosphere. In one embodiment, the protective layer 5 covers the entire four side surfaces of the heat-dissipating adhesive layer 4, and also covers the entire four exposed side surfaces of the heat-dissipating plate 3. Here, the exposed side surface of the heat-dissipating plate 3 shall refer to a side surface of the heat-dissipating plate 3 that is not in contact with other members such as the case 7 and the sealing material 8 and the surface is in an exposed state before the protective layer 5 is formed. In another embodiment, the protective layer 5 covers the entire four side surfaces of the heat-dissipating adhesive layer 4, and also covers about ½ of the exposed height of the exposed heat-dissipating plate 3 on the four side surfaces of the heat-dissipating plate 3. In another embodiment, the protective layer 5 may discontinuously cover the four side surfaces of the heat-dissipating adhesive layer 4, and there may be an uncovered portion of about 10% per side surface. The protective layer 5 may or may not be in contact with the back surface of the laminated substrate of the semiconductor module. The protective layer 5 may or may not be in contact with the case constituting the semiconductor module.

In this specification, the height of the protective layer 5 shall refer to the thickness of the protective layer 5 in the same direction as the height direction of the heat-dissipating plate 3 and the heat-dissipating adhesive layer 4. The width of the protective layer 5 shall refer to the thickness of the protective layer 5 in a direction perpendicular to each side surface of the heat-dissipating adhesive layer 4. The height of the protective layer 5 depends on the height of the heat-dissipating adhesive layer 4 and is at least equal to or greater than the height of the heat-dissipating adhesive layer 4. The height of the protective layer 5 is equal to or less than the sum of the exposed height of the heat-dissipating plate 3 and the height of the heat-dissipating adhesive layer 4. The width of the protective layer 5 may be constant over the periphery of the heat-dissipating adhesive layer 4 or may have different parts, but is preferably 0.5 mm or more, and preferably 4 mm or less. If the width of the protective layer 5 is 0.5 mm or more, it can cover the heat-dissipating plate 3 and the heat-dissipating adhesive layer 4 even if the width varies depending on the location, and can suppress pump-out of the heat-dissipating adhesive layer 4. Setting the width of the protective layer 5 to 4 mm or less prevents it from protruding from the edge of the case.

The protective layer 5 is formed by curing a composition for a protective layer that includes a silicone compound (silicone rubber-based adhesive) and a filler. The silicone compound may be a polysiloxane with a siloxane bond as its main skeleton, and may be one that has been cured at room temperature or at 80 to 100° C. by adding a vulcanizing agent such as an organic peroxide. As the filler, inorganic compound particles with high thermal conductivity can be used, and Al₂O₃ (alumina), SiO₂ (silica), BN (boron nitride), etc., can be used, but the material is not limited to these. The average particle size of the filler can be 10 to 200 μm, and is preferably 20 to 100 μm. A proportion of the filler in the total mass of the protective layer 5 (protective layer filler loading) is preferably 60 to 98% by mass. In particular, when the filler is alumina, it is preferably 75 to 98% by mass, and when the filler is boron nitride, it is preferably 60 to 75% by mass.

Preferable physical properties of the protective layer 5 after curing are a tensile strength of 0.2 to 4.5 MPa, a Shore A hardness of greater than 50 and less than 70, and an elongation at break of 100 to 400%. The tensile strength of the protective layer 5 after curing is more preferably 0.2 to 3 MPa. When the value is in this range, the reliability evaluated by a heat cycle test of the semiconductor device can be improved by two times or more compared to the case in which no protective layer is provided. The tensile strength of the protective layer 5 after curing is even more, and is preferably 0.4 to 2.5 MPa. When the value is in this range, the reliability can be improved by three times or more compared to the case in which no protective layer is provided. It was confirmed that the Young's modulus of the protective layer 5 after curing has almost no effect on reliability. The Young's modulus is the slope in the elastic region of a stress-strain diagram, and the tensile strength is the maximum stress until fracture when a tensile load is applied, and it is a physical property value that includes plastic regions such as elongation characteristics.

It is preferable that the physical properties of the heat-dissipating adhesive layer 4 and the protective layer 5 have a predetermined relationship. In particular, a ratio of the tensile strength of the protective layer 5 to the tensile strength of the heat-dissipating adhesive layer 4 may be 1.25 to 45, and is preferably 1.25 to 26. When the value is in this range, the reliability evaluated by a heat cycle test of the semiconductor device can be made two times or more compared to the case in which no protective layer is provided. The tensile strength ratio is more preferably 1.25 to 20. When the value is in this range, the reliability of the semiconductor device evaluated by a heat cycle test can be made three times or more compared to the case in which no protective layer is provided. The tensile strength ratio is even more preferably 1.25 to 10. When the value is in this range, the reliability of the semiconductor device evaluated by a heat cycle test can be made 3.5 times or more compared to the case in which no protective layer is provided.

When further comparing other physical properties of the heat-dissipating adhesive layer 4 and the protective layer 5, the protective layer 5 has a larger elongation after curing, and also has a greater Shore A hardness. The adhesion of the protective layer 5 to copper or a copper alloy may be equal to or less than the adhesion of the heat-dissipating adhesive layer 4 to copper or a copper alloy. By forming the heat-dissipating adhesive layer 4 and the protective layer 5 from such different materials, pump-out of the heat-dissipating adhesive layer 4 can be effectively suppressed by the protective layer 5.

Next, embodiments of the positional relationship and specifications of the heat-dissipating plate 3, the heat-dissipating adhesive layer 4, the cooling component 6, and the protective layer 5, which are the heat-dissipating structure portion, will be described in more detail with reference to the drawings.

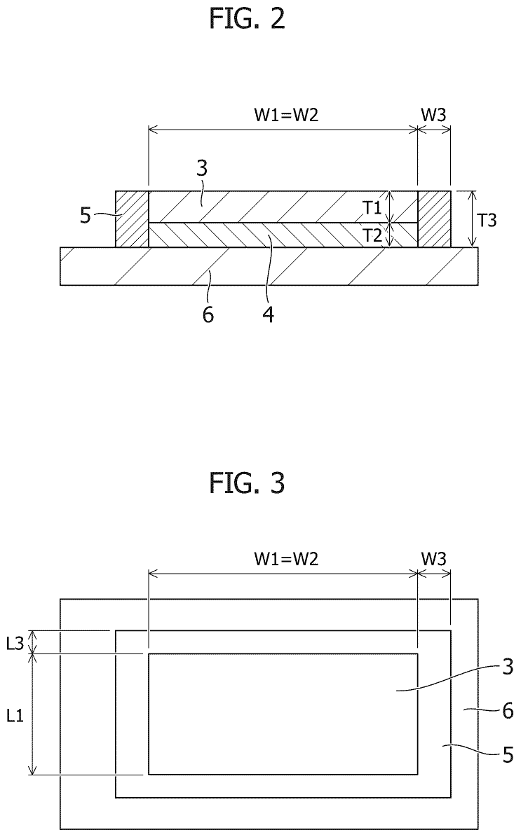

FIG. 2 is a cross-sectional view of the heat-dissipating structure portion according to the first embodiment, and FIG. 3 is a plan view of the heat-dissipating structure portion according to the first embodiment, viewed from the semiconductor module towards the cooling component. Since the heat-dissipating structure portion is manufactured by being bonded to a semiconductor module, it does not actually exist in the state of FIGS. 2 and 3, but in FIGS. 2 and 3, the semiconductor module portion is not shown for the purpose of simplifying the drawings. The protective layer 5 may exist beyond the width of the semiconductor module, or may exist inside the width of the semiconductor module.

Hereinafter, a depth of the heat-dissipating plate 3 is denoted as L1, a width as W1, and a height as T1. A depth of the heat-dissipating adhesive layer 4 is denoted as L2, a width as W2, and a height as T2. The dimensions of the principal surfaces of the heat-dissipating plate 3 and the heat-dissipating adhesive layer 4 are determined by the depth L in the short-side direction and the width W in the long-side direction. For the protective layer, a width in the depth direction is denoted as L3, a width in the width direction as W3, and a height as T3. L3 and W3 may be the same. In the illustrated embodiment, for example, L1=L2=30 mm, W1=W2=50 mm, T1=0.2 to 1 mm, T2=0.1 to 0.3 mm, L3=W3=0.5 to 4 mm, and T3=0.2 to 1 mm, but the values are not limited to these. It is also necessary to satisfy T2≤T3<(T1+T2). If the widths L3 and W3 are 0.5 mm or more, pump-out can be prevented without the protective layer 5 peeling off. The widths W3 and L3 of the protective layer 5 do not have to be uniform, and it is sufficient that they fall within the aforementioned preferable range.

In the first embodiment shown in FIGS. 2 and 3, the shapes of the principal surfaces of the heat-dissipating plate 3 and the heat-dissipating adhesive layer 4 are the same. By arranging the heat-dissipating structure portion according to the first embodiment, an advantage is obtained in that heat diffusion from the heat-dissipating plate 3 to the cooling component 6 is performed efficiently.

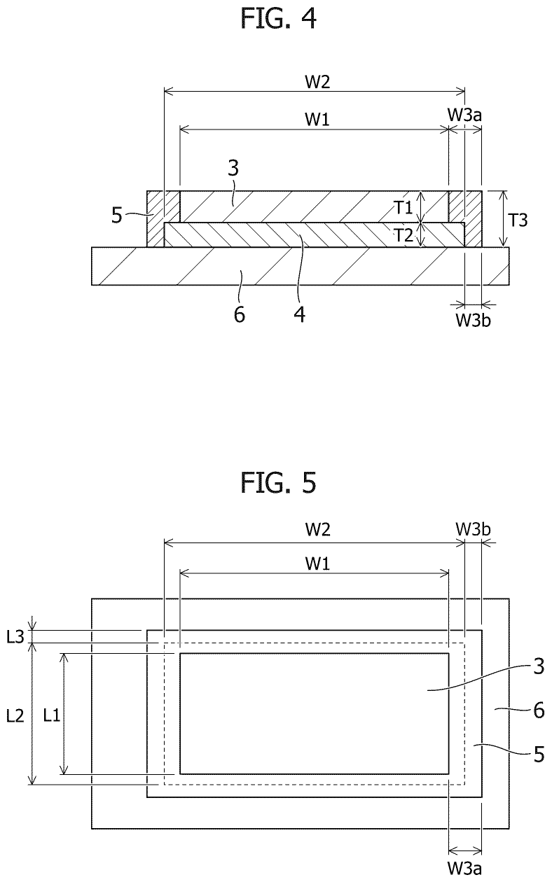

FIG. 4 is a cross-sectional view of the heat-dissipating structure portion according to the second embodiment, and FIG. 5 is a plan view of the heat-dissipating structure portion according to the second embodiment, viewed from the semiconductor module towards the cooling component. Similarly to FIGS. 2 and 3, in FIGS. 4 and 5, the semiconductor module portion is not shown for the purpose of simplifying the drawings. The reference signs related to the dimensions of the heat-dissipating plate 3 and the heat-dissipating adhesive layer 4 are the same as in the first embodiment. In the second embodiment, the width of the protective layer 5 is not uniform over the entire area, but is formed in two steps. This is because the depth L2 and width W2 of the heat-dissipating adhesive layer 4 are larger than the depth L1 and width W1 of the heat-dissipating plate 3. The value of L2−L1 is preferably about 1 to 7 mm, and the value of W2−W1 is preferably about 1 to 7 mm. At this time, if a portion of the protective layer with a larger width is defined as a first width W3a and a portion with a smaller width as a second width W3b, it is preferable that the second width W3b be 0.5 mm or more. That is, if the width W3a (first width) of the protective layer 5 covering the side surface of the heat-dissipating adhesive layer 4 is 0.5 mm or more, the heat-dissipating plate 3 and the heat-dissipating adhesive layer 4 can be covered even if the width of the protective layer 5 varies depending on the location. By making W3a 4 mm or less, the heat-dissipating adhesive layer 4 becomes less likely to pump out, and it will not protrude from the edge of the case. Since a large thickness of the protective layer 5 increases the amount of deformation due to temperature changes and makes peeling more likely to occur, it is preferable that the thickness be 4 mm or less.

In the second embodiment shown in FIGS. 4 and 5, the principal surface of the heat-dissipating adhesive layer 4 is formed larger than the principal surface of the heat-dissipating plate 3. By arranging the heat-dissipating structure portion according to the second embodiment, the adhesion area between the protective layer 5 and the heat-dissipating adhesive layer 4 becomes larger, which provides an advantage in that the adhesion between the heat-dissipating plate 3 and the cooling component 6 is improved. In contrast to the second embodiment shown in FIGS. 4 and 5, the depth L2 and width W2 of the heat-dissipating adhesive layer 4 can also be formed smaller than the depth L1 and width W1 of the heat-dissipating plate 3. In that case, the protective layer 5 may completely cover the second principal surface of the heat-dissipating plate 3, which is the surface in contact with the heat-dissipating adhesive layer 4, or may be partially in contact with it. By making the principal surface of the heat-dissipating adhesive layer 4 smaller than the principal surface of the heat-dissipating plate 3, there is an advantage in that the adhesion area can be reduced, the amount of deformation applied to the heat-dissipating adhesive layer 4 can be reduced, and peeling can be suppressed.

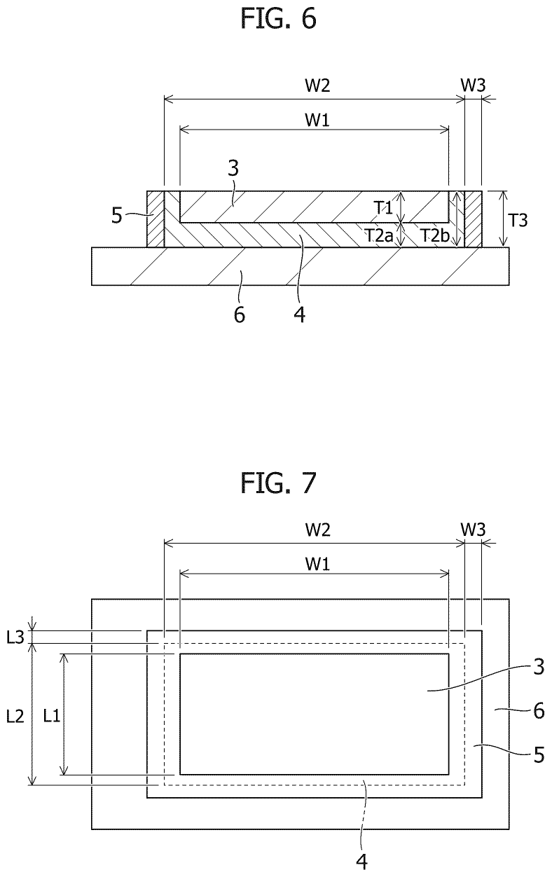

FIG. 6 is a cross-sectional view of the heat-dissipating structure portion according to the third embodiment, and FIG. 7 is a plan view of the heat-dissipating structure portion according to the third embodiment, viewed from the semiconductor module towards the cooling component. Similarly to FIGS. 2 to 5, in FIGS. 6 and 7, the semiconductor module portion is not shown for the purpose of simplifying the drawings. The reference signs related to the dimensions of the heat-dissipating plate 3 and the protective layer 5 are the same as in the first embodiment. In the third embodiment, the heat-dissipating adhesive layer 4 is not flat, but is formed in a shape having a recess. Therefore, the height of the heat-dissipating adhesive layer 4 is not uniform over the entire area, but is formed in two steps: T2a, which corresponds to the distance between the first and second principal surfaces, and T2b, which corresponds to the distance between a surface on the same plane as the first principal surface of the heat-dissipating plate 3 and the second principal surface. This is because the heat-dissipating adhesive layer 4 is provided so as to surround the heat-dissipating plate 3 by contacting the four side surfaces of the heat-dissipating plate 3 in addition to the second principal surface of the heat-dissipating plate 3. At this time, the value of L2−L1 is preferably about 1 to 7 mm, and the value of W2−W1 is preferably about 1 to 7 mm. That is, if the width of the heat-dissipating adhesive layer 4 covering the side surface of the heat-dissipating plate 3 is 0.5 mm or more, the side surface of the heat-dissipating plate 3 can be covered, and by making it about 4 mm or less, the heat dissipation from the side surface of the heat-dissipating plate 3 can be improved.

In the third embodiment shown in FIGS. 6 and 7, these members are arranged so that the heat-dissipating adhesive layer 4 surrounds the heat-dissipating plate 3. By arranging the heat-dissipating structure portion according to the third embodiment, an advantage is obtained in that the adhesion between the heat-dissipating plate 3 and the cooling component 6 via the heat-dissipating adhesive layer 4 is improved, the exposed portion of the side surface of the heat-dissipating plate 3 is eliminated, and partial discharge between the end of the heat-dissipating plate 3 and the cooling component 6 can be suppressed.

The semiconductor device according to the present invention will be described from the viewpoint of its manufacturing method. First, a semiconductor module is manufactured. For the semiconductor module, a back surface electrode of the semiconductor element 1 is bonded to the laminated substrate 2 with the joining layer 9, and a conductive connection member such as a lead frame, an aluminum wire, and/or an implant pin (not shown) is bonded to a terminal or an electrode. Next, a step of bonding the first principal surface of the heat-dissipating plate 3 to the back surface of the laminated substrate 2 with solder or a metal nanoparticle joining material is performed. When the first conductive plate 21 also serves as the heat-dissipating plate 3, this step can be omitted. The case 7 is attached to this, and the case 7 is filled with the sealing material 8, thereby sealing these members to be sealed with the sealing material 8, and the lid 10 is attached. Although not shown, a caseless semiconductor module can be manufactured by placing a member to be sealed in a suitable mold and filling the mold with a sealing material, followed by heat curing. The manufacture of the semiconductor module can be performed by a common method well known to one skilled in the art.

Next, a step of forming the heat-dissipating adhesive layer 4 on the second principal surface of the heat-dissipating plate 3, or a step of forming the protective layer 5, so as to be in contact with the side surface of the heat-dissipating plate 3 and optionally the back surface of the semiconductor module, is performed. Either the formation of the heat-dissipating adhesive layer 4 and the formation of the protective layer 5 may be performed first, and the manufacturing method may differ depending on the arrangement of the heat-dissipating plate 3, the heat-dissipating adhesive layer 4, and the protective layer 5.

When forming the heat-dissipating adhesive layer 4 before the protective layer 5, a composition for a heat-dissipating adhesive layer is applied to the second principal surface of the heat-dissipating plate 3 and cured for a predetermined time according to the curing conditions of the composition. The curing conditions vary depending on the ingredients of the composition, but for example, it can be left to stand at room temperature in the air for 24 hours to allow moisture in the air to react with siloxane units in the composition. Thereafter, a composition for a protective layer is applied to the side surface of the heat-dissipating adhesive layer 4 and optionally a part of the second principal surface of the heat-dissipating adhesive layer 4, and optionally, the side surface of the heat-dissipating plate 3. At this time, it is preferable to apply the protective layer 5 so that it protrudes from the second principal surface of the heat-dissipating adhesive layer 4 to the side in which the cooling component 6 is mounted. More specifically, it is preferable to apply the composition so that the height of the protective layer 5 after curing is about 0.05 to 0.2 mm higher than the design height, and as a result, it protrudes about 0.05 to 0.2 mm toward the cooling component 6 from the second principal surface of the heat-dissipating adhesive layer 4. After applying the composition for the protective layer, it is cured for a predetermined time according to the curing conditions of the composition. The curing conditions vary depending on the components of the composition, but for example, it can be cured at room temperature or heated at 80 to 100° C. for about 0.5 to 1 hour. After the protective layer 5 has cured, the cooling component 6 can be mounted on the protective layer 5 and the heat-dissipating adhesive layer 4 by pressure-bonding the cooling component 6 to them. The pressure-bonding force can be 200 to 300 N, preferably 240 to 260 N, and this step can be performed at room temperature. By mounting the cooling component 6 by applying pressure to the protective layer 5 in this way, the protective layer 5 can be extended in a direction parallel to the principal surfaces of the heat-dissipating adhesive layer 4 and the heat-dissipating plate 3, and in a direction outward from the center of the heat-dissipating adhesive layer 4 and the heat-dissipating plate 3. This allows a heat-dissipating adhesive layer 4 and a protective layer 5 with a uniform layer thickness to be obtained.

When forming the protective layer 5 before the heat-dissipating adhesive layer 4, the composition for a protective layer is applied to necessary locations and is cured so that the heat-dissipating plate 3, the subsequently formed heat-dissipating adhesive layer 4, and the protective layer 5 satisfy a predetermined arrangement. It is preferable to apply the protective layer 5 so that it protrudes toward the cooling component 6 from the second principal surface of the heat-dissipating adhesive layer 4 that is subsequently formed. Next, a composition for a heat-dissipating adhesive layer is applied to the second principal surface of the heat-dissipating plate 3 and is cured. The conditions for mounting the cooling component 6 may be the same as when forming the heat-dissipating adhesive layer 4 before the protective layer 5.

The manufacture of the heat-dissipating structure portion according to the first embodiment can be carried out as described above. The manufacture of the heat-dissipating structure portion according to the second and third embodiments is carried out by a method of forming the protective layer 5 before the heat-dissipating adhesive layer 4. At this time, in order to form the protective layer 5 into the predetermined structure shown in FIGS. 4 and 6, it is preferable to use a mold such as a metal mask during application.

According to the semiconductor device and its manufacturing method of the embodiments of the present invention, the side surface of the heat-dissipating adhesive layer 4 is covered by the protective layer 5 having predetermined physical properties, so that the locations in which the heat-dissipating adhesive layer 4 is exposed can be eliminated or be made very small. This makes it possible to prevent degradation and pump-out of the heat-dissipating adhesive layer 4 and provide a highly reliable semiconductor device.

### EXAMPLES

Hereinafter, the present invention will be described in more detail by giving examples of the present invention. However, the present invention is not limited to the scope of the following examples.

### Manufacture of Semiconductor Devices of Examples and Comparative Examples

For reliability evaluation, a semiconductor device for 0.75 kV was fabricated. As the laminated substrate, one was used that was formed by laminating a Cu conductive plate with a thickness of 0.8 mm as a first conductive plate, an insulating substrate with a thickness of 0.2 mm, and a Cu conductive plate with a thickness of 2 mm as a second conductive plate. An Si power semiconductor element was disposed on the laminated substrate by solder bonding in an N₂ reflow furnace, and a case was attached. An epoxy sealing material was injected into the case and was cured to obtain a power semiconductor module.

In the Examples, the heat-dissipating structure portion shown in FIGS. 2 and 3 was manufactured. The first principal surface of the heat-dissipating plate 3 was solder-bonded to the back surface of the semiconductor module. As the heat-dissipating plate 3, a Cu plate with a depth L1=30 mm, a width W1=50 mm, and a height T1=0.5 mm was used. The heat-dissipating adhesive layer 4 was formed on the second principal surface of the heat-dissipating plate 3. The composition for the heat-dissipating adhesive layer 4 was prepared by filling a silicone compound (SDP-5040-A/B, manufactured by Shin-Etsu Chemical Co., Ltd.) with Al₂O₃ (average particle size 70 μm) as a filler. The Al₂O₃ filling amount was 95% by mass for Comparative Example 1 and Examples 1 to 6 (for a tensile strength of 0.1 MPa), 92% by mass for Examples 7 to 10 (for a tensile strength of 0.2 MPa), and 90% by mass for Examples 11 to 14 (for a tensile strength of 0.5 MPa). This is the mass % of Al₂O₃ when the total mass of the composition for the heat-dissipating adhesive layer 4 is taken as 100%. The heat-dissipating adhesive layer 4 was manufactured by applying the composition for the heat-dissipating adhesive layer 4 to the heat-dissipating plate 3 and curing it at room temperature for 24 hours in the air. The heat-dissipating adhesive layer 4 after curing was made to have a depth L2=30 mm, a width W2=50 mm, and a height T2=0.1 mm.

Next, the protective layer 5 was applied in a manner such that it contacted the back surface of the semiconductor module and completely covered the entire side surfaces of the heat-dissipating plate 3 and the heat-dissipating adhesive layer 4. The composition for the protective layer 5 was prepared by filling a silicone compound (silicone rubber-based adhesive) with Al₂O₃ (average particle size 70 μm) or BN (boron nitride) (average particle size 30 μm). The compound and filling amount of the filler of the protective layer 5 in each example are shown in Table 1. The protective layer 5 was applied to have a height T3′=0.7 mm and a width W3′=2 mm, and was cured at room temperature for 24 hours. The cooling component 6 was pressure-bonded to the protective layer 5 using 250 N, and the cooling component 6 was mounted on the heat-dissipating adhesive layer 4 and the protective layer 5. In the semiconductor device after manufacturing obtained in this manner, the protective layer had a height T3=0.6 mm and a width W3=2 mm.

The semiconductor device of Comparative Example 1 was manufactured in the same manner as in the Examples, except that a protective layer was not provided.

### <Reliability Evaluation Method>

The reliability of the semiconductor device was evaluated by a thermal cycle (H/C) test. For the thermal cycle, one cycle was defined as 5 minutes at −45° C. and 5 minutes at +155° C., and the number of cycles until pump-out, cracking, or peeling of the heat-dissipating adhesive layer occurred was evaluated. Pump-out, cracking, and peeling were confirmed by observation with a microscope. A number of cycles of 1000 cyc or more is particularly preferable, because it can be evaluated as providing sufficient reliability even when the environmental load is increased, for example.

### <Tensile Strength Measurement Method>

The Young's modulus and tensile strength of the protective agent and the heat-dissipating adhesive layer were determined from a stress-strain curve based on JIS K 6251.

The results are shown in Tables 1 and 2.

TABLE 1

| | Comparative | | | | | | |
|---|---|---|---|---|---|---|---|
| | Example 1 | Example 1 | Example 2 | Example 3 | Example 4 | Example 5 | Example 6 |
| Tensile | 0.1 | 0.1 | 0.1 | 0.1 | 0.1 | 0.1 | 0.1 |
| strength of | | | | | | | |
| heat- | | | | | | | |
| dissipating | | | | | | | |
| adhesive | | | | | | | |
| layer (MPa) | | | | | | | |
| Tensile | — | 0.2 | 0.9 | 1.9 | 2.6 | 3.2 | 4.5 |
| strength of | | | | | | | |
| protective | | | | | | | |
| layer (MPa) | | | | | | | |
| Tensile | — | 2 | 9 | 19 | 26 | 32 | 45 |
| strength ratio | | | | | | | |
| (protective | | | | | | | |
| layer/heat- | | | | | | | |
| dissipating | | | | | | | |
| adhesive | | | | | | | |
| layer) | | | | | | | |
| Young's | — | 0.2 | 1.38 | 0.01 | 0.6 | 225 | 150 |
| modulus of | | | | | | | |
| protective | | | | | | | |
| layer (MPa) | | | | | | | |
| Protective | Al₂O₃ | Al₂O₃ | Al₂O₃ | Al₂O₃ | BN | BN | BN |
| layer filler | | | | | | | |
| Protective | 95 | 90 | 85 | 80 | 75 | 65 | 60 |
| layer filler | | | | | | | |
| loading (% | | | | | | | |
| by mass) | | | | | | | |
| H/C (number | 300 | 1400 | 1050 | 1000 | 700 | 450 | 400 |
| of cycles) | | | | | | | |

TABLE 2

| | Example | Example | Example | Example | Example | Example | Example | Example |
|---|---|---|---|---|---|---|---|---|
| | 7 | 8 | 9 | 10 | 11 | 12 | 13 | 14 |
| Tensile strength | 0.2 | 0.2 | 0.2 | 0.2 | 0.5 | 0.5 | 0.5 | 0.5 |
| of heat- | | | | | | | | |
| dissipating | | | | | | | | |
| adhesive layer | | | | | | | | |
| (MPa) | | | | | | | | |
| Tensile strength | 0.25 | 0.9 | 1.9 | 2.6 | 0.9 | 1.9 | 2.6 | 3.2 |
| of protective | | | | | | | | |
| layer (MPa) | | | | | | | | |
| Tensile strength | 1.25 | 4.5 | 9.5 | 13 | 1.8 | 3.8 | 5.2 | 6.4 |
| ratio | | | | | | | | |
| (protective | | | | | | | | |
| layer/heat- | | | | | | | | |
| dissipating | | | | | | | | |
| adhesive layer) | | | | | | | | |
| Young's | 0.2 | 1.38 | 0.01 | 0.6 | 1.38 | 0.11 | 0.6 | 225 |
| modulus of | | | | | | | | |
| protective layer | | | | | | | | |
| (MPa) | | | | | | | | |
| Protective layer | Al₂O₃ | Al₂O₃ | Al₂O₃ | BN | Al₂O₃ | Al₂O₃ | BN | BN |
| filler | | | | | | | | |
| Protective layer | 90 | 85 | 80 | 75 | 85 | 80 | 75 | 65 |
| filler loading (% | | | | | | | | |
| by mass) | | | | | | | | |
| H/C (number of | 1300 | 1200 | 1100 | 1000 | 1500 | 1200 | 1100 | 850 |
| cycles) | | | | | | | | |

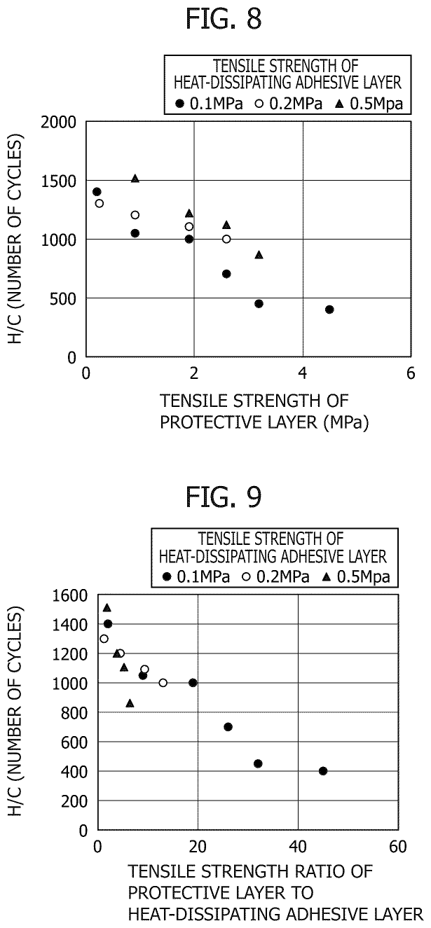

FIG. 8 is a graph plotting the number of heat cycles against the tensile strength of the protective layer in the semiconductor devices of Examples 1 to 14. FIG. 9 is a graph plotting the number of heat cycles against the ratio of the tensile strength of the protective layer to the tensile strength of the heat-dissipating adhesive layer (tensile strength ratio: tensile strength of protective layer/tensile strength of heat-dissipating adhesive layer) in the semiconductor devices of Examples 1 to 14. The semiconductor device of Comparative Example 1 is not shown in the graph because it was not provided with a protective layer, but its number of heat cycles was 300. That is, the thermal cycle characteristics of all the semiconductor devices of Examples 1 to 14 were improved compared to the semiconductor device of Comparative Example 1, and if the tensile strength of the protective layer after curing is 0.2-4.5 MPa, the thermal cycle characteristics were improved by 30% or more compared to the comparative example. Also, extrapolating from each point in FIG. 8, when the tensile strength is 0.2 to 3 MPa, the thermal cycle characteristics are improved by 66% or more, and if it is 0.4 to 2.5 MPa, the number of cycles becomes 1000 or more, and it was confirmed that the characteristics are improved by 330% or more. Among these, when the tensile strength ratio is from 1.25 to 40, the thermal cycle characteristics are improved by 200% or more, and when it is from 1.25 to 20, they are improved by 300% or more, which was confirmed to be even more preferable. On the other hand, it was found that the Young's modulus of the protective layer does not have a significant effect on the thermal cycle characteristics. This is presumed to be due to Young's modulus being a value related to the deformation of a material, whereas tensile strength is a value related to the fracture of a material.

It was confirmed from the examples of the present invention that by setting the tensile strength of the protective layer to a predetermined value, pump-out, cracking, and peeling of the heat-dissipating adhesive layer in the heat-dissipating structure portion of the semiconductor device can be suppressed. On the other hand, it was confirmed that the Young's modulus of the protective layer has almost no relation to reliability. The present invention can provide a highly reliable power semiconductor device.

### REFERENCE SIGNS LIST

1 semiconductor element
2 laminated substrate
21 second conductive plate
22 insulating substrate
23 first conductive plate
3 heat-dissipating plate
4 heat-dissipating adhesive layer
5 protective layer
6 cooling component
7 case
8 sealing material
9 joining layer
10 lid

What is claimed is:

1. A semiconductor device comprising:
a semiconductor module in which a laminated substrate on which a semiconductor element is mounted is sealed with a sealing material;
a heat-dissipating plate bonded to the laminated substrate;
a heat-dissipating adhesive layer provided in contact with the heat-dissipating plate, the layer including a rubber elastic body and a filler;
a cooling component provided in contact with the heat-dissipating adhesive layer; and
a protective layer that covers at least a part of a surface of the heat-dissipating adhesive layer,
wherein the protective layer includes a silicone compound and a filler, and has a tensile strength of 0.2 to 4.5 MPa.

2. The semiconductor device according to claim 1, wherein a ratio of the tensile strength of the protective layer to the tensile strength of the heat-dissipating adhesive layer is 1.25 to 26.

3. The semiconductor device according to claim 1, wherein the tensile strength of the protective layer is 0.2 to 3 MPa.

4. The semiconductor device according to claim 1, wherein, in the protective layer, the silicone compound includes polysiloxane, and the filler includes Al₂O₃ (alumina) or BN (boron nitride).

5. The semiconductor device according to claim 1, wherein the filler of the protective layer is included in an amount of 60% by mass or more and 98% by mass or less with respect to a total mass of the protective layer.

6. The semiconductor device according to claim 1, wherein the protective layer is provided discontinuously along a periphery of the heat-dissipating adhesive layer.

7. The semiconductor device according to claim 1, wherein a width of the protective layer is 0.5 mm or more.

8. A method for manufacturing the semiconductor device according to claim 1, the method comprising steps of:
preparing the semiconductor module in which the heat-dissipating plate is bonded to a back surface of the laminated substrate;
forming the heat-dissipating adhesive layer in contact with the heat-dissipating plate;
forming the protective layer, wherein the protective layer is formed so as to protrude from a principal surface of the heat-dissipating adhesive layer; and
pressure-bonding the cooling component to the protruding protective layer and bringing the cooling component and the heat-dissipating adhesive layer into contact.

9. The method according to claim 8, wherein the step of forming the protective layer is performed before the step of forming the heat-dissipating adhesive layer.

10. The method according to claim 8, wherein the step of forming the heat-dissipating adhesive layer is performed before the step of forming the protective layer.

11. The method according to claim 8, wherein the step of pressure-bonding is performed with a force of 200 to 300 N.
